(19) United States
(12) Patent Application Publication
(10) Pub. No.: US 2014/0103322 A1
(43) Pub. Date: Apr. 17, 2014

(54) DISPIRODIBENZONAPHTHACENE COMPOUND AND ORGANIC LIGHT-EMITTING DEVICE HAVING THE SAME

(71) Applicants: Taiki Watanabe, Akishima-shi (JP); Naoki Yamada, Inagi-shi (JP); Jun Kamatani, Tokyo (JP); Kengo Kishino, Tokyo (JP); Akihito Saitoh, Gotemba-shi (JP)

(72) Inventors: Taiki Watanabe, Akishima-shi (JP); Naoki Yamada, Inagi-shi (JP); Jun Kamatani, Tokyo (JP); Kengo Kishino, Tokyo (JP); Akihito Saitoh, Gotemba-shi (JP)

(73) Assignee: CANON KABUSHIKI KAISHA, Tokyo (JP)

(21) Appl. No.: 14/118,189

(22) PCT Filed: Apr. 23, 2012
(86) PCT No.: PCT/JP2012/061506

§ 371 Date: Nov. 15, 2013

(30) Foreign Application Priority Data
May 18, 2011 (JP) 2011-111505

(51) Int. Cl. H01L 51/00; H01L 51/50

(52) U.S. Cl. CPC H01L 51/0056; H01L 51/5028
USPC 257/40; 585/27

(57) ABSTRACT

The present invention provides a novel organic compound having high thermal stability and can form a stable amorphous thin-film and also provides an organic light-emitting device having a high luminous efficiency and a low driving voltage.

The present invention relates to a dispirodibenzonaphthacene compound represented by the following Formula [1]:

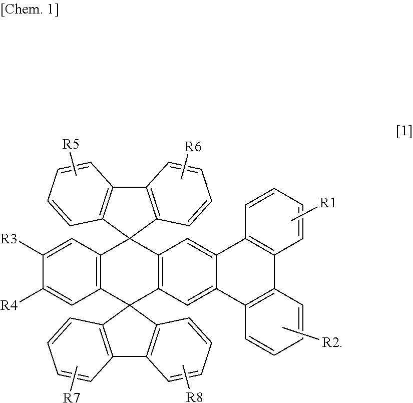

### TECHNICAL FIELD

The present invention relates to a dispirodibenzonaphthacene compound and an organic light-emitting device having the compound.

### BACKGROUND ART

An organic light-emitting device includes an anode, a cathode, and an organic compound layer disposed between the electrodes. In the organic light-emitting device, holes and electrons injected from the electrodes are recombined in the organic compound layer serving as a light-emitting layer to generate excitons, and the excitons emit light when they return to their ground state. Recent progress in organic light-emitting device is considerable, and a low driving voltage, diversity in emission wavelength, rapid responsiveness, and reductions in size and weight can be achieved in light-emitting device.

An organic light-emitting device that emits phosphorescence (hereinafter referred to as a phosphorescent device) includes a phosphorescent material in a light-emitting layer and harvests light from triplet excitons. In the phosphorescent devices, there is a demand for further improvement in luminous efficiency.

NPL 1 describes a method of synthesizing compound A-1 shown below.

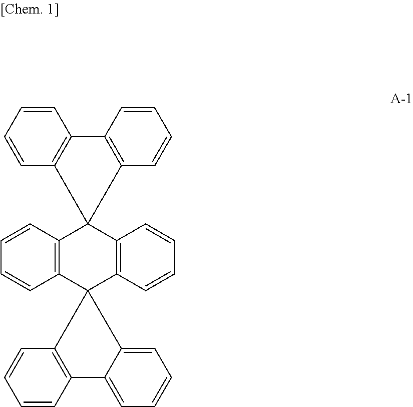 [SMILES: c1ccc2c(c1)-c1ccccc1C21c2ccccc2C2(c3ccccc3-c3ccccc32)c2ccccc21]

PTL 1 describes a material for a phosphorescent device. The material is compound A-1 substituted with an aryl group, such as compound A-2 shown below.

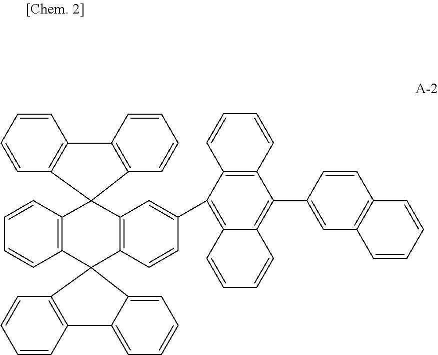 [SMILES: c1ccc2c(c1)-c1ccccc1C21c2ccccc2C2(c3ccccc3-c3ccccc32)c2cc(-c3c4ccccc4c(-c4ccc5ccccc5c4)c4ccccc34)ccc21]

Compound A-1 disclosed in NPL 1 and compound A-2 disclosed in PTL 1 are dispiroanthracene compounds. Compound A-1 has a highly symmetrical structure and easily causes a whitening phenomenon (crystallization) when it is formed into a thin film to increase the driving voltage of an organic light-emitting device.

Compound A-2 has a structure where an aromatic hydrocarbon group containing anthracene is introduced into compound A-1. Anthracene has a minimum excited triplet level (hereinafter referred to as T1 energy) of about 680 nm, and, therefore, use of compound A-2 as a material (in particular, as a host material) for a blue phosphorescent device decreases the luminous efficiency.

### CITATION LIST

### Patent Literature

PTL 1 International Patent Publication No. WO02/088274

### Non Patent Literature

NPL 1 Journal of American Chemical Society, Vol. 52, 1930, p. 2881

### SUMMARY OF INVENTION

The present invention provides dispirodibenzonaphthacene compounds represented by the following Formula [1]:

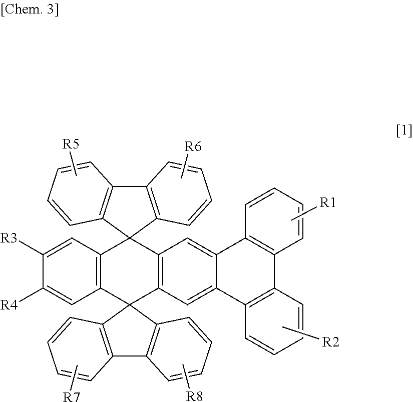

In Formula [1], R1 to R8 are each independently selected from the group consisting of hydrogen atoms and alkyl groups having 1 to 4 carbon atoms.

### BRIEF DESCRIPTION OF DRAWINGS

FIG. 1 is a schematic cross-sectional view illustrating organic light-emitting devices and switching devices connected to the organic light-emitting devices.

### DESCRIPTION OF EMBODIMENT

The dispirodibenzonaphthacene compounds according to aspects of the present invention are represented by the following Formula [1]:

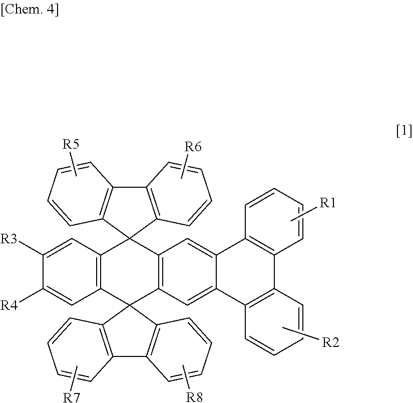

In Formula [1], R1 to R8 are each independently selected from the group consisting of hydrogen atoms and alkyl groups having 1 to 4 carbon atoms.

As shown by solid lines in Formula [1], specific benzene rings independently have R1 to R8.

Examples of the alkyl group having 1 to 4 carbon atoms include methyl groups, ethyl groups, iso-propyl groups, and tert-butyl groups.

The dispirodibenzonaphthacene compounds represented by Formula [1] are each superior to compound A-1 or compound A-2 in the following three properties.

Firstly, the dispirodibenzonaphthacene compound can form a stable amorphous film. Compound A-1 has high molecular symmetry due to C2 symmetry and has a low molecular weight. Such a structure easily causes crystallization. On the other hand, the compound according to the present invention has an asymmetry structure and a higher molecular weight than compound A-1 and is therefore hardly crystallized. Accordingly, vacuum deposition or spin coating of the compound represented by Formula [1] forms a stable amorphous film that is hardly crystallized.

Secondly, the dispirodibenzonaphthacene compound has high thermal stability. Compound A-2 has a freely rotating substituent (anthracenyl group) that binds to dispiroanthracene of the mother skeleton. On the other hand, the compound represented by Formula [1] according to the present invention does not have a freely rotating bond excluding the substituents R's (R1 to R8 in the formula). In addition, since R's are not aryl groups, their bonds are hardly cleaved by thermal energy.

Thirdly, the dispirodibenzonaphthacene compound has a high T1 energy. When R's (all of R1 to R8) of the compound represented by Formula [1] according to the present invention are hydrogen atoms, the T1 energy is 446 nm (2.78 eV), which is very high. For example, in the case of a compound having an aryl group (anthracenyl group), such as compound A-2, the compound has a low T1 energy due to the aryl group. In contrast to this, the compound represented by Formula [1] does not have any aryl group having a low T1 energy and thereby has a high T1 energy.

Incidentally, the T1 energy is determined as the first emission peak when a spectrum of a toluene solution (1×10⁻⁴ mol/L) of the phosphorescence-emitting component cooled to 77K is measured at an excitation wavelength of 350 nm. The measurement is performed with a spectrometer U-3010 manufactured by Hitachi, Ltd.

In addition to the above-mentioned three properties, the compound according to the present invention has a property that the energy gap (hereinafter referred to as Δ(S1-T1)) between the minimum excited singlet level (S1) and the minimum excited triplet level (T1) is small.

The reasons and effects that are believed by the present inventors will be described below.

The mother skeleton of the compounds according to the present invention is shown below. The compounds of the present invention are each basically composed of three moieties: one unit I moiety and two unit II moieties. The two unit II moieties twist with respect to the unit I moiety to thereby form a spiro structure.

The carbons that form the spiro structure, i.e., carbon atoms at the positions shown with reference numerals 1 and 2 in the structural formula below are quaternary carbons, and thereby the conjugation between unit I and unit II is cut off at the carbons.

The dibenzonaphthacene loses the electronic properties due to the spiro structure and is divided into benzene moieties and a triphenylene moiety as shown by the arrows in the structural formula below. Consequently, the dispirodibenzonaphthacene compound of the present invention has physical properties highly reflecting the properties of triphenylene itself.

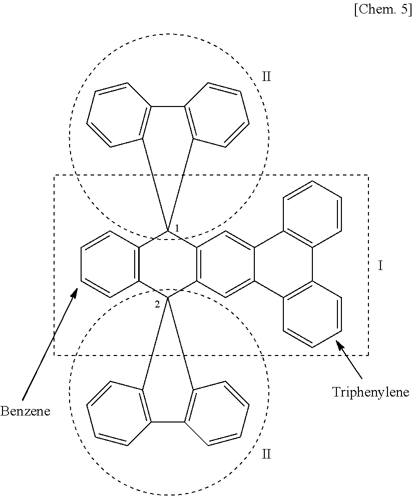

Table 1 shows T1 energy and Δ(S1-T1) values of triphenylene and other aromatic hydrocarbons. As shown in Table 1, triphenylene has a high T1 energy (427 nm), which is higher than those of other aromatic hydrocarbons excluding benzene, and a small Δ(S1-T1) (83 nm).

As a result, the compound of the present invention has a high T1 energy, i.e., 470 nm or less, and a small Δ(S1-T1) of 120 nm or less.

TABLE 1

| Name | Structural formula | T1 | Δ (S1-T1) |
|---|---|---|---|
| Benzene | 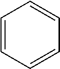 | 339 nm | 126 nm |
| Triphenylene | 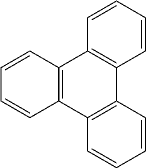 [SMILES: c1ccc2c(c1)c1ccccc1c1ccccc21] | 427 nm | 83 nm |
| Biphenylene | 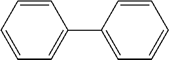 [SMILES: c1ccc(-c2ccccc2)cc1] | 436 nm | 150 nm |
| Terphenylene | 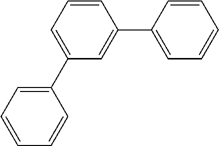 [SMILES: c1ccc(-c2cccc(-c3ccccc3)c2)cc1] | 445 nm | 138 nm |
| Phenanthrene | 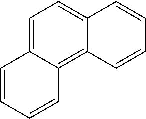 [SMILES: c1ccc2c(c1)ccc1ccccc12] | 459 nm | 151 nm |
| Napthalene | 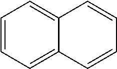 | 472 nm | 158 nm |
| Chrysene | 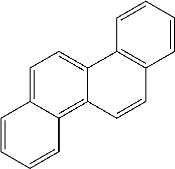 [SMILES: c1ccc2c(c1)ccc1c3ccccc3ccc21] | 500 nm | 169 nm |
| Pyrene | 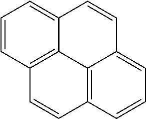 [SMILES: c1cc2ccc3cccc4ccc(c1)c2c34] | 589 nm | 251 nm |
| Perylene | 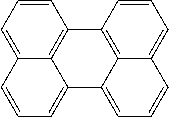 [SMILES: c1cc2cccc3c4cccc5cccc(c(c1)c23)c54] | 806 nm | 379 nm |
| Anthracene | 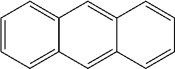 [SMILES: c1ccc2cc3ccccc3cc2c1] | 688 nm | 310 nm |

The compound of the present invention has a high T1 energy, i.e., 470 nm or less, and can be therefore used in an organic light-emitting device as a host material of the light-emitting layer that includes a guest material emitting blue phosphorescence. This is because that the emission peak wavelength of a guest material emitting blue phosphorescence is 470 nm or less.

In blue light emission, the maximum peak wavelength of an emission spectrum is 470 nm or less, and the T1 energy of a host material is required to be higher than that of the guest material. In the case of a host material having a larger T1 energy than 470 nm as a wavelength equivalent (the case of a low energy), leakage of the T1 energy occurs when the T1 energy moves from the host material to the guest material. The dispirodibenzonaphthacene compound of the present invention has a T1 energy of 470 nm or less and can be therefore used in a blue phosphorescent device.

Use of a compound having a high Δ(S1-T1) as the host material of an organic light-emitting device emitting phosphorescence increases the driving voltage. Electrons move in the orbit of S1 energy of the host material and recombine with holes. Incidentally, the energy level of S1 is higher than that of T1. A large Δ(S1-T1) value, more specifically, a high energy level of S1 increases the driving voltage of the organic light-emitting device.

Accordingly, in order to reduce the driving voltage of an organic light-emitting device emitting blue phosphorescence, the compound used as the host material of the light-emitting layer is required to have a small Δ(S1-T1) of 120 nm or less, such as 100 nm or less. In the case of a Δ(S1-T1) value higher than 120 nm, even if the T1 energy is high, the S1 energy is also high, resulting in a high driving voltage of the organic light-emitting device. The S1 energy level of the host material is higher than 350 nm, i.e., a lower energy level. This is because no organic light-emitting device is designed so as to emit light in the ultraviolet region where the excitation energy level is higher than the energy level of the host material.

The dispirodibenzonaphthacene compound of the present invention has properties reflecting the properties of triphenylene as a structural unit. Specifically, the Δ(S1-T1) value of the compound is a value of approximately the Δ(S1-T1) value (83 nm) of triphenylene itself, i.e., 120 nm or less, such as 100 nm or less.

Use of the compound of the present invention as a host material of a light-emitting layer of an organic light-emitting device will be described.

The compound of the present invention, i.e., the dispirodibenzonaphthacene compound is used mainly in the light-emitting layer of an organic light-emitting device.

The light-emitting layer may be constituted of a plurality of components, and the components can be classified into a main component or an accessory component. The main component has a largest weight ratio in all components constituting the light-emitting layer and is referred to as a host material.

Compounds other than the main component are the accessory components and can be referred to as a guest material (or dopant material), a light-emitting assist material, and a charge injecting material. The light-emitting assist material and the charge injecting material may be the same organic compound having the same structure or may be organic compounds having different structures. These accessory components may be referred to as a second or third host material for being distinguished from the guest material.

The guest material is a compound that contributes to light emission in the light-emitting layer. The host material is a compound which is present around the guest material as a matrix in the light-emitting layer and which mainly contributes to carrier transport and donation of excitation energy to the guest material.

The concentration of the guest material is 0.01 wt % or more and 50 wt % or less, such as 0.1 wt % or more and 20 wt % or less, based on the total amount of the materials constituting the light-emitting layer. Furthermore, in order to prevent concentration quenching, the concentration of the guest material may be 10 wt % or less. In addition, the guest material may be contained uniformly or with a concentration gradient over the entire layer including the host material or partially contained in a specific region to provide a host material layer not containing the guest material.

The dispirodibenzonaphthacene compound of the present invention can be used as the host material of the light-emitting layer as described above.

Specific structural formulae of the dispirodibenzonaphthacene compounds according to aspects of the present invention are exemplified below.

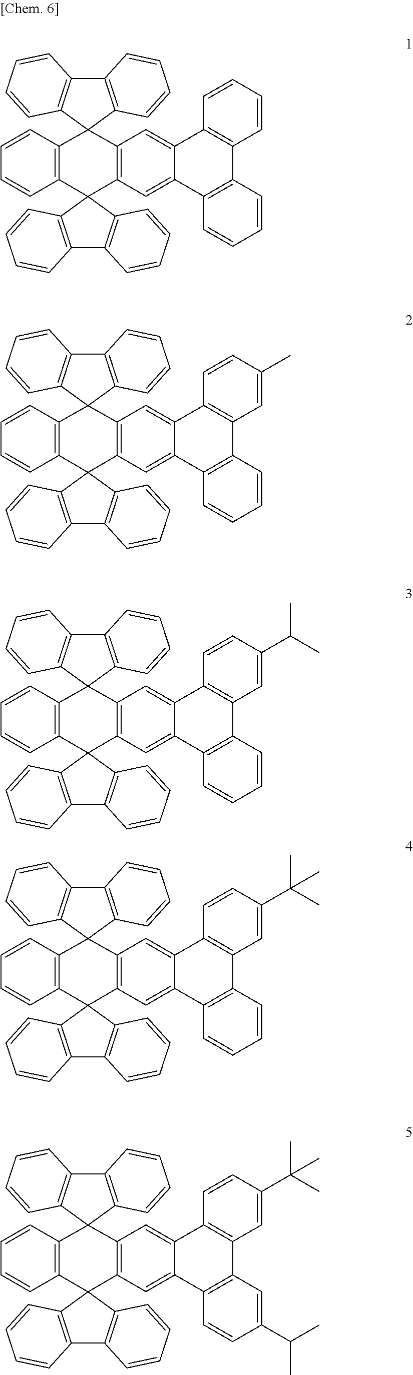

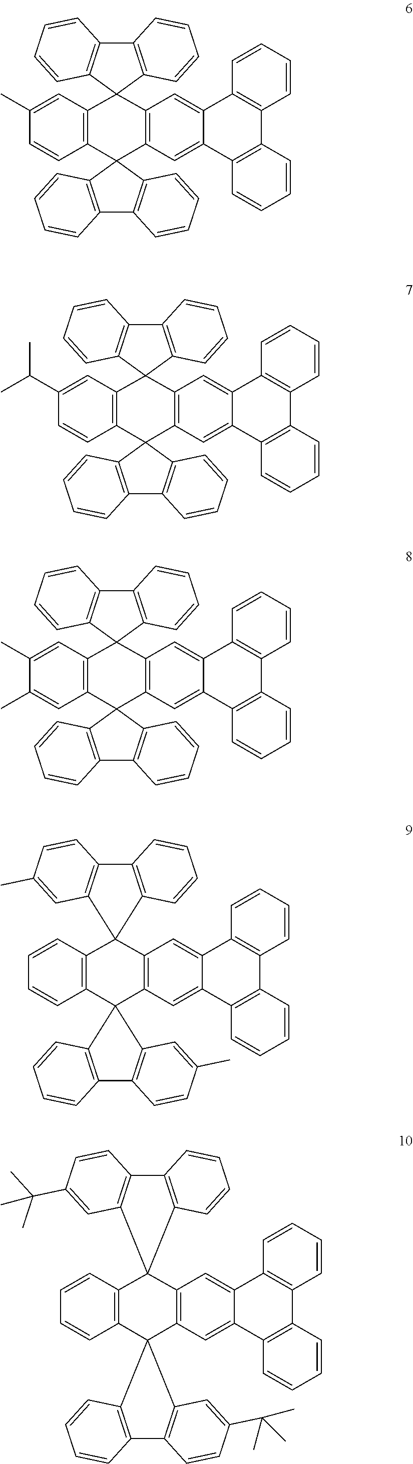

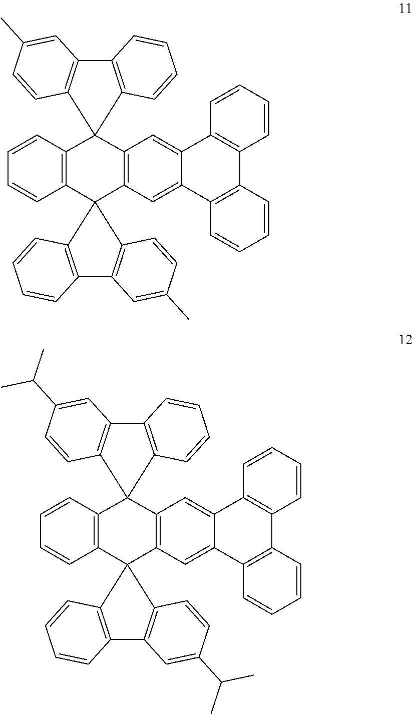

In the case using a dispirodibenzonaphthacene compound of the present invention in an organic light-emitting device, the compound may be purified by sublimation just before the application of the compound to the device. Purification by sublimation is effective for providing an organic compound with high purity. In such purification by sublimation, purification of an organic compound having a higher molecular weight generally requires a higher temperature, and thereby thermal decomposition due to the high temperature tends to occur. Accordingly, the organic compound used in the organic light-emitting device can have a molecular weight of 1000 or less so that the sublimation purification can be performed without requiring excessive heating.

The organic light-emitting device according to this embodiment includes a pair of electrodes, an anode and a cathode, and an organic compound layer disposed therebetween. The organic compound layer is a device having the organic compound according to an aspect of the present invention.

Examples of the organic light-emitting device produced using the organic compound according to an aspect of the present invention include those having a configuration composed of an anode, a light-emitting layer, and a cathode disposed in this order on a substrate. Other examples of the organic light-emitting device include those having a configuration where an anode, a hole-transporting layer, an electron-transporting layer, and a cathode are disposed in this order; those having a configuration where an anode, a hole-transporting layer, a light-emitting layer, an electron-transporting layer, and a cathode are disposed in this order; those having a configuration where an anode, a hole-injecting layer, a hole-transporting layer, a light-emitting layer, an electron-transporting layer, and a cathode are disposed in this order; and those having a configuration where an anode, a hole-transporting layer, a light-emitting layer, a hole/exciton-blocking layer, an electron-transporting layer, and a cathode are disposed in this order. These five types of multi-layer examples merely show quite basic device configurations, and the organic light-emitting device using the compound according to the present invention is not limited thereto. The compound according to the present invention is used as a host material of the light-emitting layer as described above and also may be appropriately used in, for example, the hole-injecting layer, the hole-transporting layer, the electron-transporting layer, or the hole/exciton-blocking layer.

In the case of using the compound of the present invention as a host material, the above-described guest material emitting blue phosphorescence or a guest material emitting blue to green phosphorescence having an emission peak in the region of 440 to 530 nm can be used.

Emission of phosphorescence by a guest material can be confirmed by the following method. Phosphorescence has a long emission lifetime (on the order of μS), and the excitation energy is therefore lost by collision with solvent molecules, vibration of molecules, or oxygen. Consequently, light emission is hardly observed or is very weak at room temperature under an oxygen atmosphere. Accordingly, emission of phosphorescence is confirmed by purging a dilute solution (10⁻³ mol/L or less) of the guest material with nitrogen and cooling the solution with, for example, liquid nitrogen and visually observing whether or not strong light emission can be obtained by irradiation with an ultraviolet lamp.

The organic light-emitting device according to this embodiment can optionally contain, in addition to the organic compound according to the present invention, known materials, such as a hole-injecting material, a hole-transporting material, a host material, a guest material, an electron-injecting material, or an electron-transporting material. These materials may be a low-molecular system or a high-molecular system.

Examples of these materials will be described below.

The hole-injecting material or the hole-transporting material can be a material possessing high hole mobility. Examples of low-molecular or high-molecular system material having hole-injecting ability or hole-transporting ability include, but not limited to, triarylamine derivatives, phenylenediamine derivatives, stilbene derivatives, phthalocyanine derivatives, porphyrin derivatives, poly(vinylcarbazole), poly(thiophene), and other electrically conductive polymers.

Examples of the host material include, but not limited to, triarylamine derivatives, phenylene derivatives, condensed ring aromatic compounds (e.g., naphthalene derivatives, phenanthrene derivatives, fluorene derivatives, and chrysene derivatives), organic metal complexes (e.g., organic aluminum complexes such as tris(8-quinolinolato)aluminum, organic beryllium complexes, organic iridium complexes, and organic platinum complexes), and polymer derivatives such as poly(phenylenevinylene) derivatives, poly(fluorene) derivatives, poly(phenylene) derivatives, poly(thienylenevinylene) derivatives, and poly(acetylene) derivatives.

Examples of the guest material include phosphorescent Ir complexes and platinum complexes shown below.

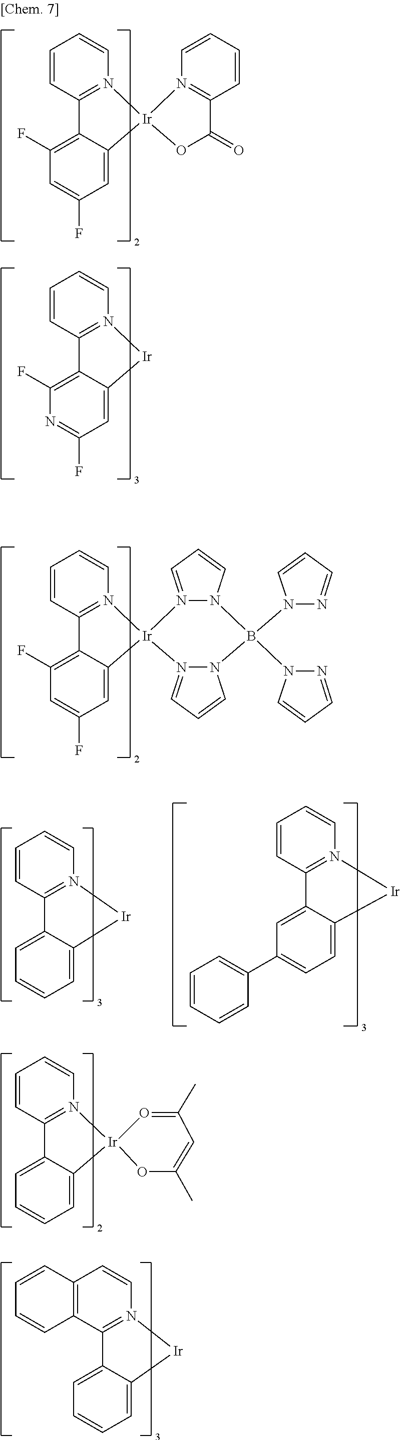

As the guest material, a fluorescent dopant also can be used. Examples of the fluorescent dopant include condensed ring compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, organic beryllium complexes, and polymer derivatives such as poly(phenylenevinylene) derivatives, poly(fluorene) derivatives, and poly(phenylene) derivatives.

The electron-injecting material or the electron-transporting material are selected with consideration for, for example, the balance with the hole mobility of the hole-injecting material or the hole-transporting material. Examples of the material possessing the electron-injecting ability or the electron-transporting ability include, but not limited to, oxadiazole derivatives, oxazole derivatives, pyrazine derivatives, triazole derivatives, triazine derivatives, quinoline derivatives, quinoxaline derivatives, phenanthroline derivatives, and organic aluminum complexes.

The material of the anode has a high work function. Examples of such a material include simple metals such as gold, platinum, silver, copper, nickel, palladium, cobalt, selenium, vanadium, and tungsten; alloys of these simple metals; and metal oxides such as tin oxide, zinc oxide, indium oxide, indium tin oxide (ITO), and indium zinc oxide. Electrically conductive polymers such as polyaniline, polypyrrole, and polythiophene also can be used. These electrode materials may be used alone or in combination of two or more thereof. The anode may have either a monolayer structure or a multilayer structure.

The material of the cathode has a low work function. Examples of such materials include alkali metals such as lithium; alkaline earth metals such as calcium; simple metals such as aluminum, titanium, manganese, silver, lead, and chromium; alloys of these simple metals such as magnesium-silver, aluminum-lithium, and aluminum-magnesium; and metal oxides such as indium tin oxide (ITO). These electrode materials can be used alone or in combination of two or more thereof. The cathode may have either a monolayer structure or a multilayer structure.

In the organic light-emitting device according to this embodiment, a layer containing the organic compound according to this embodiment and a layer of another organic compound are generally formed by vacuum deposition, ionic vapor deposition, sputtering, plasma CVD, or a known method of applying the compound dissolved in a suitable solvent (e.g., spin coating, dipping, casting, an LB method, or an ink jet method). In a layer formed by vacuum deposition or application of a solution, for example, crystallization hardly occurs to achieve high long-term stability. In the case of forming a layer by application of a solution, the solution may additionally contain an appropriate binder resin.

Examples of the binder resin include, but not limited to, polyvinylcarbazole resins, polycarbonate resins, polyester resins, ABS resins, acrylic resins, polyimide resins, phenol resins, epoxy resins, silicone resins, and urea resins. These binder resins may be singly used as a homopolymer or a copolymer or as a mixture of two or more of polymers. The solution for forming a layer may further contain an additive such as a known plasticizer, antioxidant, or ultraviolet absorber.

The organic light-emitting device according to the present invention can be applied to a display or a lighting system. In the lighting system, devices at practical level have been being actively developed for achieving target quality of a lighting device, such as luminous efficiency, luminance, average color rendering index, and lifetime. The compound according to the present invention can be used in such a lighting system. Examples of the lighting system also include see-through lighting panels where the background can be seen and bendable flexible lighting panels.

In addition, the organic light-emitting device including the compound according to the present invention can be used, for example, in an exposing source of an electrophotographic image-forming apparatus or in a backlight of a liquid crystal display.

The display has the organic light-emitting device according to the present invention in a display section. The display section has a pixel, and the pixel has the organic light-emitting device according to the present invention. The display can be used as an image-displaying apparatus of, for example, a PC.

The display may be used in the display section of an image pickup apparatus such as a digital camera or a digital video camera. The image pickup apparatus includes the display section and an image pickup section having an image pickup optical system for imaging. The display section displays an image to be pickup or a pickup image. Analog image information input from an image input section is input into the display section as digital image information. The display section has a plurality of pixels, and the pixels are the organic light-emitting devices. The organic light-emitting devices are connected to switching devices. Thus, the organic light-emitting device according to the present invention is used in the image input apparatus where an image is input as image information to display the image at the display section.

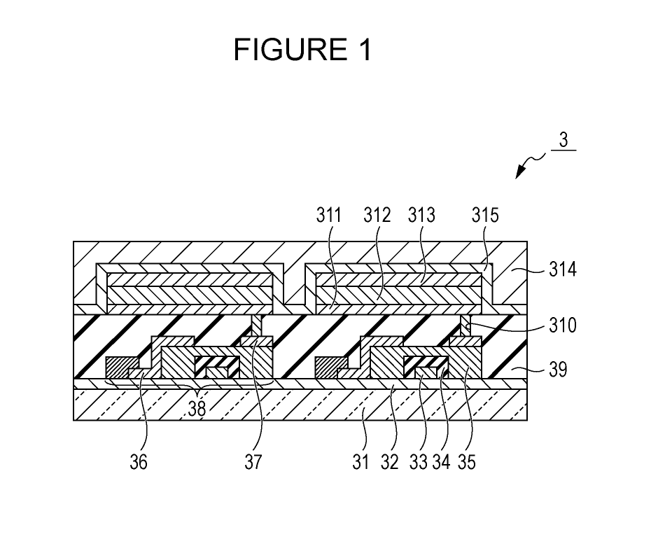

FIG. 1 is a schematic cross-sectional view of an image-displaying apparatus having organic light-emitting devices in a pixel section. This figure shows two organic light-emitting devices and two TFT devices. One organic light-emitting device is connected to one TFT.

In the drawing, reference numeral 3 denotes an image-displaying apparatus, reference numeral 38 denotes a TFT device serving as a switching device, reference numeral 31 denotes a substrate, reference numeral 32 denotes a moisture-proof film, reference numeral 33 denotes a gate electrode, reference numeral 34 denotes a gate-insulating film, reference numeral 35 denotes a semiconductor layer, reference numeral 36 denotes a drain electrode, reference numeral 37 denotes a source electrode, reference numeral 39 denotes an insulating film, reference numeral 310 denotes a contact hole, reference numeral 311 denotes an anode, reference numeral 312 denotes an organic layer, reference numeral 313 denotes a cathode, reference numeral 314 denotes a first protective layer, and reference numeral 315 denotes a second protective layer.

The image-displaying apparatus 3 includes a substrate 31 such as a glass substrate and a moisture-proof film 32 disposed on the substrate 31 for protecting the members (TFT devices or the organic layer) formed on the substrate. The moisture-proof film 32 is constituted of, for example, silicon oxide or a complex of silicon oxide and silicon nitride. A gate electrode 33 is disposed on the moisture-proof film 32. The gate electrode 33 can be formed by sputtering a metal such as Cr.

A gate-insulating film 34 is disposed so as to cover the gate electrode 33. The gate-insulating film 34 is formed, for example, by plasma CVD or catalyst chemical vapor deposition (cat-CVD) of silicon oxide and patterning the resulting film. Furthermore, a semiconductor layer 35 is disposed so as to cover the gate-insulating film 34 patterned at each region which will be used as a TFT. This semiconductor layer 35 is, for example, a silicon film formed by plasma CVD (and optionally annealing at, for example, 290° C. or more) and patterning the resulting film into a circuit shape.

Furthermore, each semiconductor layer 35 is provided with a drain electrode 36 and a source electrode 37. Thus, a TFT device 38 includes the gate electrode 33, the gate-insulating film 34, the semiconductor layer 35, the drain electrode 36, and the source electrode 37. An insulating film 39 is disposed on the TFT device 38. A contact hole (through hole) 310 is provided in the insulating film 39 to connect the source electrode 37 and an anode 311 made of a metal for the organic light-emitting device.

On this anode 311, an organic layer 312 of a multilayer including a light-emitting layer or a light-emitting monolayer and a cathode 313 are sequentially stacked to constitute an organic light-emitting device as a pixel. In order to prevent deterioration of the organic light-emitting device, a first protective layer 314 or a second protective layer 315 may be provided.

The switching device of the display according to this embodiment is not particularly limited and may be, for example, an MIM device or an a-Si transistor device. The switching device may be disposed on a semiconductive surface. The semiconductive surface is, for example, a surface of a silicon substrate. The silicon substrate is, for example, a monocrystal silicon substrate.

### EXAMPLES

The present invention will be described in detail by the following examples, but is not limited thereto.

### Example 1

### Synthesis of Example Compound 1

Example Compound 1 was synthesized by the following scheme.

2,3-Dibromoanthraquinone, which is compound E-1 as a raw material, can be easily synthesized by the method described in Tetrahedron Letters, 45 (12), 2511-2513 (2004). Another raw material, compound E-2, is commercially available and was purchased from Wako Pure Chemical Industries, Ltd.

Compound E-3 was prepared by a Suzuki coupling reaction of compound E-1 and compound E-2. The methods of synthesizing compound E-4 and thereafter will be described in detail.

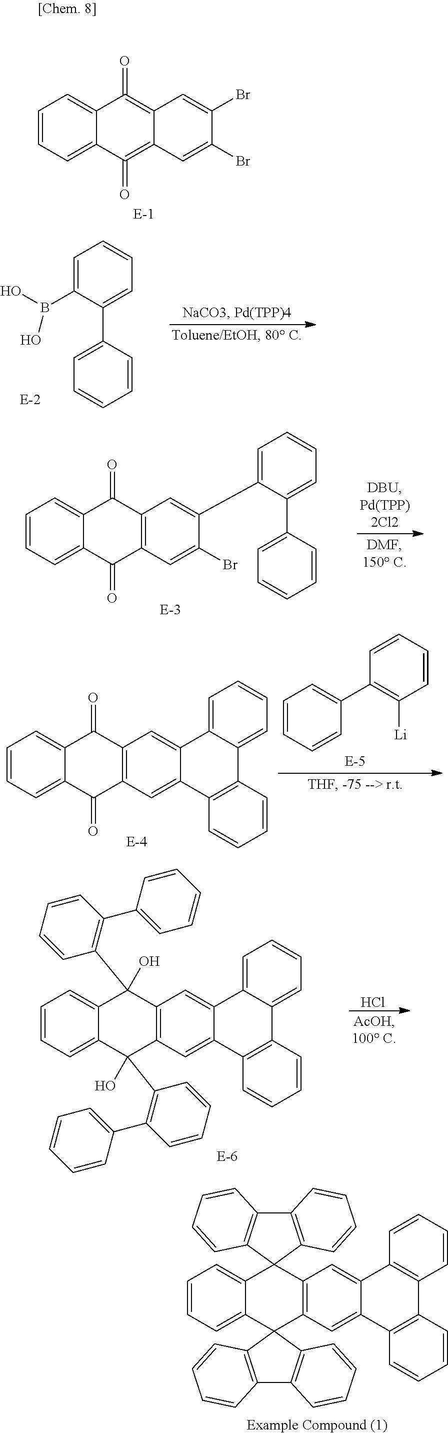

### Synthesis of Compound E-4

In a 300-mL three-neck flask, 12.6 g (28.6 mmol) of compound E-3, 7.0 g (46.0 mmol) of 1,8-diazabicyclo-5.4.0-undec-7-ene (DBU), 4.67 mmol of bis(triphenylphosphine)palladium dichloride (Pd(TPP)2Cl2), and 100 mL of dehydrated N,N-dimethylformamide (DMF) were placed, followed by stirring at 160° C. for 7 hr. After the reaction, the solvent was removed, and 100 mL of chloroform was added thereto. The resulting mixture was refluxed for 1 hr, followed by filtration. The filtrate was subjected to purification by column chromatography (filling material: silica gel, eluent: chloroform) to yield a yellowish brown solid. The solid was recrystallized from methanol to yield 5.5 g (yield: 53.7%) of compound E-4 as a yellow solid.

The resulting compound was identified by mass spectrometry.

The results of matrix-assisted laser desorption/ionization-time of flight mass spectrometry (MALDI-TOF-MS) were: observed value: m/z=358 and calculated value: C₂₆H₁₄O₂=358.1.

### Synthesis of Example Compound 1

In a 300-mL three-neck flask, 5.4 g (23.2 mmol) of 2-bromobiphenyl and 50 mL of dehydrated tetrahydrofuran (hereinafter referred to as THF) were placed, followed by cooling to −75° C. with a dry ice/methanol bath. To this THF solution, 14.5 mL of 1.6 mol/L of n-butyllithium was dropwise added. The resulting mixture was stirred at −75° C. for 2 hr to yield a solution of compound E-5 in THF.

To the solution of compound E-5 in THF maintained at −75° C., 0.83 g (2.3 mmol) of compound E-4 was added. The temperature of the mixture was raised to room temperature, followed by stirring for 15 hr. After completion of the reaction, the solvent was removed, and 100 mL of chloroform was added thereto. The resulting mixture was subjected to original removal treatment by column chromatography (filling material: silica gel, eluent: chloroform). After removal of the solvent, the residue was dissolved in a small amount of chloroform and was added to 200 mL of methanol to precipitate 1.2 g of crude compound E-6 as a reddish brown solid.

Subsequently, in a 100-mL flask, 1.2 g of the crude compound E-6, 40 mL of glacial acetic acid, and 3 mL of hydrochloric acid were placed, followed by reflux for 1 hr. The reaction solution was added to ice and left to stand overnight. The precipitated solid was filtered and subjected to purification by column chromatography (filling material: silica gel, eluent: chloroform) to yield a light yellow solid. The solid was recrystallized from methanol to yield 0.35 g (yield: 24% based on compound E-4) of Example Compound 1 as a white solid.

The resulting compound was identified by mass spectrometry. The S1 energy and the T1 energy were measured, and Δ(S1-T1) was calculated. Furthermore, a thin film of Example Compound 1 was formed to visually investigate whether or not crystallization occurred in the film. The results of matrix-assisted laser desorption/ionization-time of flight mass spectrometry (MALDI-TOF-MS) were: observed value: m/z=632 and calculated value: C₅₀H₃₂=632.3.

The results of measurement of S1 and T1 energies and calculation of Δ(S1-T1) were:

S1 energy: 360 nm,
T1 energy: 446 nm, and

### Δ(S1-T1)=86 nm.

The S1 energy was determined as the first emission peak when a spectrum of a toluene solution (1×10⁻⁴ mol/L) of the fluorescence-emitting component was measured at room temperature at an excitation wavelength of 310 nm. The measurement was performed with a spectrometer U-3010 manufactured by Hitachi, Ltd.

The T1 energy was determined as the first emission peak when a spectrum of a toluene solution (1×10⁻⁴ mol/L) of the phosphorescence-emitting component cooled to 77K was measured at an excitation wavelength of 350 nm. The measurement was performed with a spectrometer U-3010 manufactured by Hitachi, Ltd.

### Observation of Thin Film

An adjustment solution of 0.2 wt % of Example Compound 1 in chloroform was prepared, and about five drops of the chloroform solution was applied onto a glass plate, and the plate was rotated at a speed of 2000 rpm for 1 min with a spin coater. Subsequently, the glass plate applied with the solution was dried in an oven at 100° C. for 1 hr, followed by visual observation of conditions of the thin film formed on the glass plate. As a result, the thin film was recognized as a transparent amorphous film not having whitening.

### Example 2

### Synthesis of Example Compound 10

Example Compound 10 was synthesized by the following method.

Compound E-4 shown by the following formula was synthesized in conformity to the description in Example 1. The methods of synthesizing compound E-8 and thereafter will be described in detail.

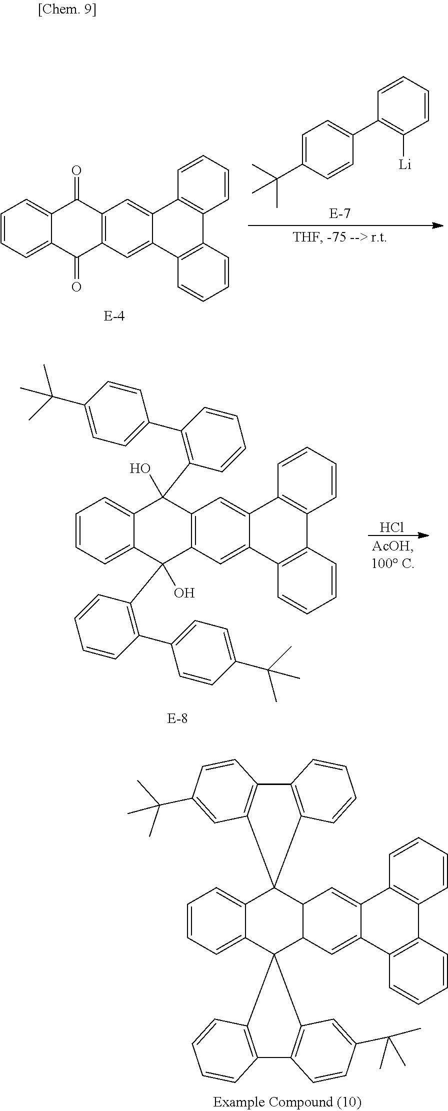

### Synthesis of Example Compound E-10

In a 300-mL three-neck flask, 5.1 g (17.6 mmol) of 2-bromo-4′-tert-biphenyl and 50 mL of dehydrated THF were placed, followed by cooling to −75° C. with a dry ice/methanol bath. To this THF solution, 11 mL of 1.6 mol/L of n-butyllithium was dropwise added. The resulting mixture was stirred at −75° C. for 2 hr to yield a solution of compound E-7 in THF.

To the solution of compound E-7 in THF maintained at −75° C., 0.65 g (1.8 mmol) of compound E-4 was added. The temperature of the mixture was raised to room temperature, followed by stirring for 15 hr. After completion of the reaction, the solvent was removed, and 100 mL of chloroform was added thereto. The resulting mixture was subjected to original removal treatment by column chromatography (filling material: silica gel, eluent: chloroform). After removal of the solvent, the residue was dissolved in a small amount of chloroform and was added to 200 mL of methanol to precipitate 0.9 g of crude compound E-8 as a reddish brown solid.

Subsequently, in a 100-mL flask, 0.9 g of the crude compound E-8, 40 mL of glacial acetic acid, and 3 mL of hydrochloric acid were placed, followed by reflux for 1 hr. The reaction solution was added to ice and left to stand overnight. The precipitated solid was filtered and subjected to purification by column chromatography (filling material: silica gel, eluent: chloroform) to yield a light yellow solid. The solid was recrystallized from methanol to yield 0.31 g (yield: 23% based on compound E-4) of Example Compound 10 as a white solid.

The resulting compound was identified by mass spectrometry. The S1 energy and the T1 energy were measured, and Δ(S1-T1) was calculated. Furthermore, a thin film of Example Compound 10 was formed to visually investigate whether or not crystallization occurred in the film. The results of matrix-assisted laser desorption/ionization-time of flight mass spectrometry (MALDI-TOF-MS) were: observed value: m/z=744 and calculated value: C₅₈H₄₆=744.4.

The results of measurement of S1 and T1 energies and calculation of Δ(S1-T1) were:

S1 energy: 361 nm,
T1 energy: 450 nm, and

### Δ(S1-T1)=89 nm.

The S1 energy was determined as the first emission peak when a spectrum of a toluene solution (1×10⁻⁴ mol/L) of the fluorescence-emitting component was measured at room temperature at an excitation wavelength of 310 nm. The measurement was performed with a spectrometer U-3010 manufactured by Hitachi, Ltd.

The T1 energy was determined as the first emission peak when a spectrum of a toluene solution (1×10⁻⁴ mol/L) of the phosphorescence-emitting component cooled to 77K was measured at an excitation wavelength of 350 nm. The measurement was performed with a spectrometer U-3010 manufactured by Hitachi, Ltd.

### Observation of Thin Film

An adjustment solution of 0.2 wt % of Example Compound 10 in chloroform was prepared, and about five drops of the chloroform solution was applied onto a glass plate, and the plate was rotated at a speed of 2000 rpm for 1 min with a spin coater. Subsequently, the glass plate applied with the solution was dried in an oven at 100° C. for 1 hr, followed by visual observation of conditions of the thin film formed on the glass plate. As a result, the film was recognized as a transparent amorphous film not having whitening.

### Example 3

In this Example, an organic light-emitting device having a configuration composed of anode/hole-injecting layer/hole-transporting layer/light-emitting layer/hole-exciton-blocking layer/electron-transporting layer/cathode disposed in this order on a substrate was produced by the following method.

A film of ITO was formed on a glass substrate by sputtering as an anode having a thickness of 120 nm, and the resulting product was used as a transparent electrically conductive support substrate (ITO substrate). On this ITO substrate, organic compound layers and electrode layers shown below were successively formed by resistance heating vacuum vapor deposition in a vacuum chamber of 10⁻⁵ Pa. On this occasion, the area of electrodes facing each other was adjusted to be 3 mm². The layers were: hole-injecting layer (40 nm): compound HT-1 hole-transporting layer (10 nm): compound HT-2, light-emitting layer (30 nm): host material: Example Compound 1, guest material: compound G-1 (weight ratio based on the weight of the host material: 10%), hole-exciton-blocking layer (10 nm): compound ET-1, electron-transporting layer (30 nm): compound ET-2, metal electrode layer 1 (1 nm): LiF, and metal electrode layer 2 (100 nm): Al.

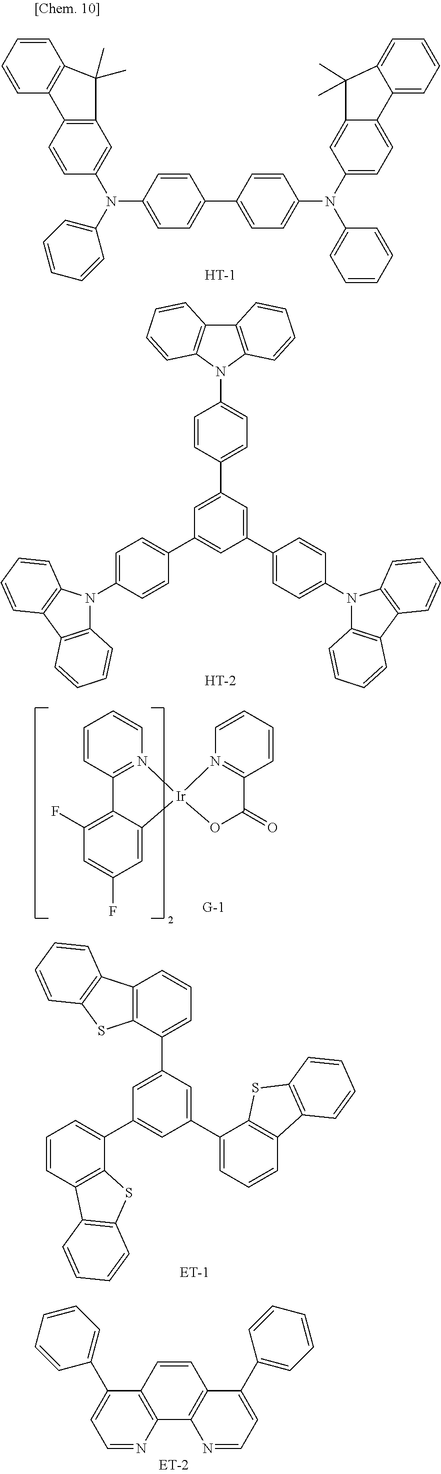

A voltage of 5.4 V was applied to the resulting organic light-emitting device using the ITO electrode as a positive electrode and the Al electrode as the negative electrode to observe emission of blue light with a luminance of 1000 cd/m², a luminous efficiency of 21 cd/A, and CIE chromaticity coordinates (0.21, 0.38).

### Example 4

An organic light-emitting device was produced as in Example 3 except that Example Compound 10 was used as the host material of the light-emitting layer instead of Example Compound 1.

A voltage of 5.2 V was applied to the resulting organic light-emitting device using the ITO electrode as a positive electrode and the Al electrode as the negative electrode to observe emission of blue light with a luminance of 1000 cd/m², a luminous efficiency of 20 cd/A, and CIE chromaticity coordinates (0.22, 0.38).

As described by the embodiment and examples above, the present invention can provide a novel dispirodibenzonaphthacene compound that has a high T1 energy and can form a stable amorphous film having high chemical stability and low crystallinity. The compound of the present invention has a novel structure having a triphenylene skeleton having a small energy gap (Δ(S1-T1)), where S1 is the minimum excited singlet level and T1 is the minimum excited triplet level, in the mother skeleton. Accordingly, an organic light-emitting device having a high luminous efficiency and a low driving voltage can be provided by using the novel dispirodibenzonaphthacene (polycyclic aromatic compound) of the present invention as a host material of a phosphorescent device. The dispirodibenzonaphthacene compound can be used in the light-emitting layer of an organic light-emitting device as a host material for a phosphorescence-emitting, blue light-emitting, or blue phosphorescence-emitting guest material.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-111505, filed May 18, 2011, which is hereby incorporated by reference herein in its entirety.

1. A dispirodibenzonaphthacene compound represented by the following Formula [1]: 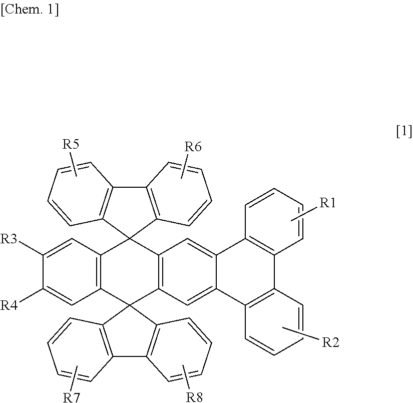
wherein, R1 to R8 are each independently selected from the group consisting of hydrogen atoms and alkyl groups having 1 to 4 carbon atoms.

2. An organic light-emitting device comprising an anode, a cathode, an organic compound layer disposed between the anode and the cathode and emitting light from between the anode and the cathode, wherein the organic light-emitting device further includes a layer, other than the organic compound layer, between the anode and the cathode, wherein
the organic compound layer is a light-emitting layer including a guest material and the dispirodibenzonaphthacene compound according to claim 1 as a host material.

3. The organic light-emitting device according to claim 2, wherein the guest material is a compound that emits phosphorescence.

4. The organic light-emitting device according to claim 2, wherein the guest material is a compound that emits blue light.

5. A display comprising a plurality of pixels, wherein the pixels each include an organic light-emitting device according to claim 2 and a switching device connected to the organic light-emitting device.

6. An image input apparatus comprising a display section for displaying an image and an input section for inputting image information, wherein the display section includes a plurality of pixels each having an organic light-emitting device according to claim 2 and a switching device connected to the organic light-emitting device.
